(19) United States
(12) Patent Application Publication
(10) Pub. No.: US 2025/0030366 A1
(43) Pub. Date: Jan. 23, 2025

(54) METHOD FOR ESTIMATING PARAMETERS OF AN ELECTRIC MOTOR AND A POWER FILTER

(71) Applicant: Danfoss Power Electronics A/S, Gråsten (DK)

(72) Inventors: Ana-Mari Tataru Kjær, Harrislee (DE); Lucian Asiminoaei, Gråsten (DK)

(21) Appl. No.: 18/774,409

(22) Filed: Jul. 16, 2024

(30) Foreign Application Priority Data
Jul. 17, 2023 (DE) 102023118879.8

(51) Int. Cl. H02P 23/14; G01R 31/34

(52) U.S. Cl. CPC H02P 23/14; G01R 31/343

(57) ABSTRACT

A method for estimating electrical parameters of an electric motor (205) and a power filter (203) connected to a power converter (201) including injecting an AC signal of different frequencies for a given time window in the power filter (203) and the motor (205), measuring a response signal of the power filter (203) and the motor (205) to the injected AC signal, determining a resonance frequency of the power filter (203) based on the measured response signal, calculating a ratio of leakage inductances of the power filter (203) and the motor (205).

### CROSS-REFERENCE TO RELATED APPLICATION

This application claims foreign priority benefits under 35 U.S.C. § 119 to German Patent Application No. 102023118879.8 filed on Jul. 17, 2023, the content of which is hereby incorporated by reference in its entirety.

### TECHNICAL FIELD

The invention disclosed herein relates to a method for estimating parameters of an electric motor and a power filter, a power converter for controlling an electric motor, and a computer program product according to the accompanied claims.

### BACKGROUND

Power converters, such as Adjustable Speed Drives (ASD) are used together with motors to achieve controllable speed and power as it is required for industrial application. The ASD provides a pulse width modulation voltage at its output for this controllable motion.

A drawback of the modulation is voltage stress on the motor windings. Therefore, output power filters, such as Sine Wave Filters (SWF) are installed at the output of a frequency converter with the purpose of filtering out high frequency components from a current flowing through the motor. Doing so, the motor isolation and bearings are protected against the high electric transients, and the motor temperature decreases, which is of interest for lowering the fire hazard and increasing lifetime of the motor.

Existing products cannot estimate the motor or filter parameters when having an output filter connected to the motor. Thus, only the motor parameter can be identified, and for this the user needs to disconnect the output filter from the system. This is a laborious, time-consuming and expensive process, which sometimes requires re-certification of the installation afterwards.

### SUMMARY

Against this background, there is need for a possibility to estimate motor and/or filter parameters when having an output filter connected to the motor.

The above identified problem is solved by a first aspect of the invention disclosed herein, which relates to a method for estimating electrical parameters of an electric motor and a power filter connected to a power converter, such as an Adjustable Speed Drive (ASD).

The method comprises injecting an AC signal of different frequencies for a given time window in the power filter and the motor, measuring a response signal of the power filter and the motor to the injected AC signal, determining a resonance frequency of the power filter based on the measured response signal, and calculating a ratio of the power filter inductance over the motor leakage inductance.

The present invention is based on a series of test signals including a so-called “frequency sweep”, which means that an AC signal of different frequencies is injected for a given time window in the power filter and the motor in order to identify the presence of a power filter and, in case a power filter is present, to identify separate parameters of the motor and the power filter.

An AC signal of different frequencies, i.e. a “frequency sweep” may be induced by varying the duty cycle, i.e. the step width of a signal output from the power converter.

The AC signal of different frequencies according to the present invention may be injected once, to determine the parameters of the power filter and motor, or twice, which is one time to detect the presence of the power filter and another time to determine the parameters of the power filter and motor.

Based on the determined parameters, the power filter and/or the motor may be controlled precisely. In particular, the determined parameters may be used identify different time constants of the power filter and the motor. Each time constant is determined by specific parameters or parameters combinations of the system.

According to an embodiment, the method continues with estimation of electrical parameters only for the motor, in case no resonance frequency of the power filter is determined.

Since in case no resonance frequency of the power filter is determined, no power filter is present and there is no need for further steps to determine parameters of the power filter. In other words, in case no resonance frequency of the power filter is determined, it is detected that no power filter is connected to the motor. Thus, a message that signals a missing power filter may be output.

According to another embodiment, the method is carried out while the filter is connected to the motor.

By using the method disclosed herein, the power filter can stay connected to the motor. Accordingly, no disconnection of the power filter and the motor is necessary and the system comprising both, the power filter and the motor can be identified, monitored and/or controlled any time, in particular periodically and/or automatically.

According to another embodiment, a sum of leakage inductances of the power filter and the motor is measured by using a small-signal step voltage test, performed at a given DC offset level.

By using a small-signal step voltage test, the leakage inductance “α” of the electric system comprising the power filter and the motor can be determined, according to equation (1), wherein “L_{f}” is the inductance of the filter and “L_{σ}” is the leakage inductance of the motor.

$$α = {L}_{f} + {L}_{σ} \qquad ( 1 )$$

According to another embodiment, inductor and capacitor (LC) resonance present in the signal measured by using the small-signal step voltage test is eliminated by use of a numerical filter, which isolates time constant intervals.

Using a numerical filter suppresses in particular resonances generated by the power filter, which overlay signals generated by the motor. Thus, eliminating the LC resonance results in a clear signal providing information for both, the power filter and the motor.

According to another embodiment, a ratio of motor and filter leakage inductances is measured by using the injected AC signal at certain level of DC offset level.

The DC offset level may be identical or derived from the small-signal step voltage test.

According to another embodiment, the injection of the AC signal of different frequencies starts from a minimum frequency up to a maximum frequency, and is monotonical increased or decreased, or random, or a given order, and covers an entire range with a given step-size.

Based on the signal measured in response to the injection of the AC signal of different frequencies, the resonance frequencies may then be identified and used to calculate the ratio of the filter inductance and motor leakage inductance according to equation (2).

$$β = \frac{{L}_{f}}{{L}_{σ}} = \frac{\frac{{ω}_{s}^{2}}{{ω}_{p}^{2}}}{1 - \frac{{ω}_{s}^{2}}{{ω}_{p}^{2}}} \qquad ( 2 )$$

The inductance of the power filter and the motor leakage inductance may be separated by combining the results from the step test and the signal measured in response to the injection of the AC signal of different frequencies according to equations (3) and (4).

$${L}_{f} = β \cdot \frac{a}{β + 1} \qquad ( 3 )$$

$${L}_{σ} = β \cdot \frac{a}{β + 1} \qquad ( 4 )$$

Based on equation (5), the filter capacitor “C_{f}” may be identified:

$${C}_{f} = \frac{1}{{L}_{σ} \cdot {f}_{s}^{2}} \qquad ( 5 )$$

According to another embodiment, further electrical parameters are calculated based on the ratio of leakage inductances of the power filter (203) and the motor (205), wherein the further electrical parameters are selected from the following list: stator resistance (Rs), rotor resistance (Rr), motor leakage inductance (Lσ), magnetizing inductance (Lh), resonance frequency of the power filter, capacitance (Cf), and filter inductance (Lf), wherein the capacitance (Cf) is also estimated for each phase individually to consider unbalanced cases of capacitor inductions.

As soon as the parameters of the power filter are known, the parameters of the motor can be identified by isolating the influence of the power filter from the measured signal.

According to an embodiment, an ESR of at least the filter capacitor is determined based on the magnitude of the peak resonant frequency of the filter capacitor.

By determining the magnitude of the peak at resonant frequency, to see if the peak decreased significantly, which means an increase in the total resistance an equivalent series resistance (ESR) of the cable, and ESR of the inductor and an ESR of the capacitor can be determined.

According to another embodiment, the further electrical parameters are used to adjust control parameters for controlling the motor and/or the power filter.

As soon as the electrical parameters of the power filter and/or the motor are known, the power filter and/or the motor may be controlled precisely by adapting the control parameters of the power converter, for example. This adaptation may be carried out periodically and/or in response to a user command.

According to an embodiment, a degradation level of the power filter component parameters, capacitances, inductances and resistances (LC or LCL) are periodically compared at different time moments against different given thresholds.

The present invention may be used to detect parameters of the motor and the power filter (Lf, Cf) and changing parameters over time as a result of degrading/aging of individual components of the motor and/or filter. The detection of changing parameter over time may be performed by acquiring a baseline of parameters, which is stored in the drive or a cloud for future comparison usage. At intervals, new parameters may be acquired and compared with the baseline parameters plus a tolerance band of acceptance, in order to detect a shift/drift in parameters. In the event that the measured motor parameters or filter parameters (baseline, actual parameter) has exceed an acceptance limit/threshold an alarm/signal and/or fault state by the Drive may be triggered.

According to another embodiment, a DC test is used for measuring stator resistance (Rs) and filter resistance (Rf) parameters, a step test is used for measuring motor leakage inductance (Lσ) und filter inductance (Lf) at four DC biases, AC tests are used for measuring magnetizing inductance (Lh) and rotor resistance (Rr) parameters, wherein the step test is performed with a current target of 25% of a nominal magnetization current, wherein from the step test and the AC tests, the nominal magnetizing current is identified, wherein the AC signal of different frequencies is injected only once at a dc bias equal to the identified nominal magnetizing current, and wherein the step test is rerun at the nominal magnetizing current with a current target of 10% of nominal motor current, such that the result of the rerun step test is the sum of motor leakage and filter inductances.

According to a second aspect, the present invention relates to a controller for controlling an electric motor, wherein the controller comprises a processor or FPGA configured to perform an embodiment of the method disclosed herein.

According to a third aspect the present invention relates to a computer program product comprising instructions which, when the program is executed by a computer, cause the computer to carry out an embodiment of the method disclosed herein.

The effects and further embodiments of the method, the controller and the computer program product according to the present invention are analogous to the effects and embodiments of the enclosure according to the description mentioned above. Thus, it is referred to the above description of the enclosure.

### BRIEF DESCRIPTION OF THE DRAWINGS

Further features, details and advantages of the invention result from the wording of the claims as well as from the following description of exemplary embodiments based on the drawings. The figures show:

FIG. 1 a flow chart of an algorithm that is based on the method disclosed herein,

FIG. 2 a circuit diagram of an electric system,

FIG. 3 an overview of response characteristics of components of the electric system according to FIG. 2, to different frequencies,

FIG. 4 an overview of tests that may be carried out using the method disclosed herein,

FIG. 5 an overview of an ASD, a controller, a power filter (LC or LCL), and a motor.

### DETAILED DESCRIPTION

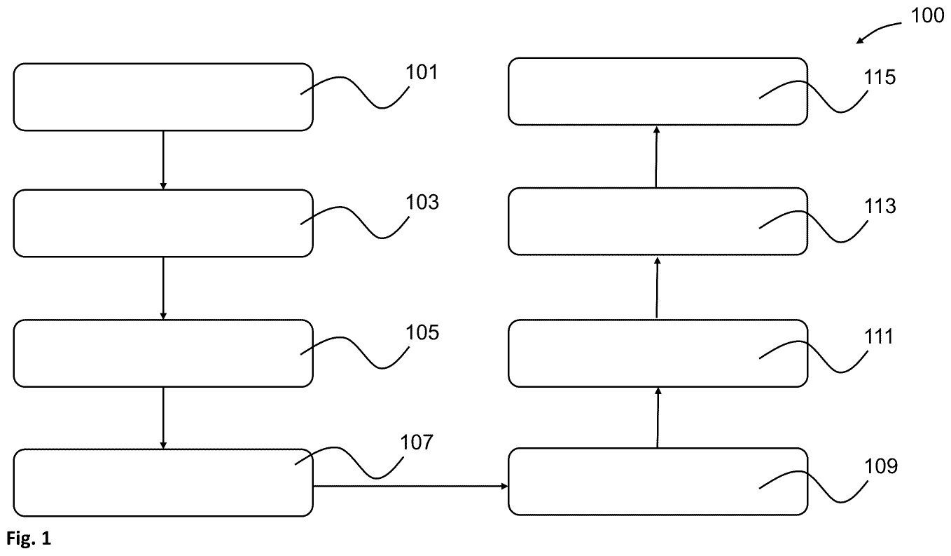

In FIG. 1, a flow chart of an algorithm 100 is shown. The algorithm 100 starts with a detection step 101, in which a so-called frequency sweep is carried out by injecting an AC signal of different frequencies for a given time window in a system, in order to identify the presence of a power filter. Thus, the AC signal is injected using a plurality of different duty cycles provided by a power converter.

If distinct resonance frequencies, i.e. frequencies that are in a range computed based on the injected AC signal or frequencies specified in a look-up table, are found in a signal output by the system in response to the injected AC signal, a flag or a message signaling that a power filter has been found, is set or generated. In response to the flag or message signaling that a power filter has been found, all settings corresponding to a system including a motor and a power filter are enabled.

In a removal step 103, a moving average filter is applied on the signal output by the system in response to injecting the AC signal, for removing the resonant components of the power filter from the measured current.

In a variation step 105, the frequency of the injected AC signal is varied, in particular increased.

In a determination step 107, power filter resistance and inductance are determined and the nominal magnetizing flux is calculated based thereon, wherein in the beginning a given set of parameters is used.

In a testing step 109, a test for determining a leakage inductance with increased pulse length and lower current target than an estimated nominal magnetization current and a sum of filter and leakage inductances is calculated.

The sum of motor and filter leakage inductances is measured by using a small-signal step voltage test, performed at a certain DC offset level, for example.

In injection step 111, an AC signal of different frequencies for a given time window is injected in the system again, for a second frequency sweep at DC bias equal to the estimated nominal magnetization current. The resonance frequencies are extracted and the ratio of filter to motor leakage inductance is calculated by applying Eq. 1.

$$α = {L}_{f} + {L}_{σ} \qquad ( 1 )$$

The frequency sweep starts from a minimum frequency up to a maximum frequency, and can be performed in any order, monotonical increased or decreased, or random, such to cover the entire range with a given step-size.

In a separation step 113, filter and motor leakage inductances are separated by applying equations 3 and 4.

$${L}_{f} = β \cdot \frac{a}{β + 1} \qquad ( 3 )$$

$${L}_{σ} = β \cdot \frac{a}{β + 1} \qquad ( 4 )$$

In a calculation step 115, a filter capacitor is calculated by applying equation 5.

$${C}_{f} = \frac{1}{{L}_{σ} \cdot {f}_{s}^{2}} \qquad ( 5 )$$

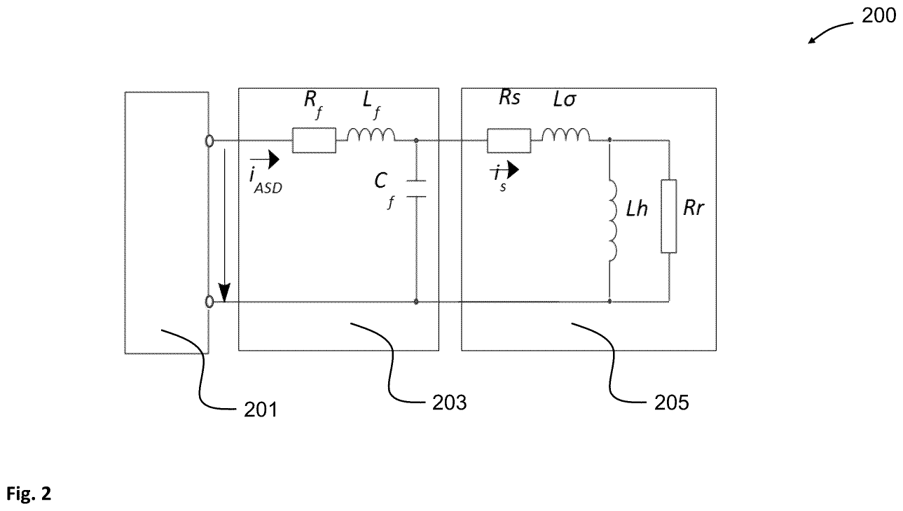

In FIG. 2, a system 200 including a power converter 201 forming an Adjustable Speed rive, a sine-wave power filter 203 and motor 205, wherein Lf is a filter inductance, Cf is a filter capacitance, Rr is rotor resistance of the motor, Lh is a magnetizing inductance Lh, and Lσ is a leakage inductance.

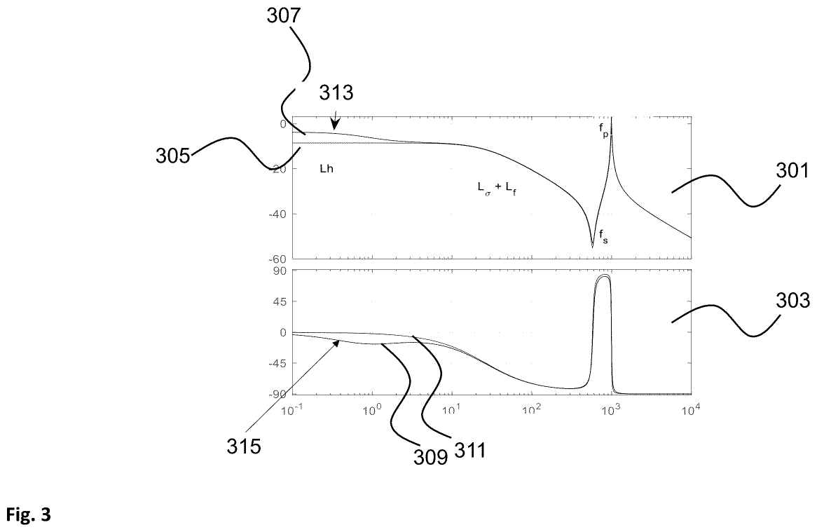

In FIG. 3, a first graph 301 is shown that shows a frequency in [Hz] on its x-axis and a magnitude in [dB] in its y-axis, and a second graph 303 that shows a frequency in [Hz] on its x-axis and a phase in [deg] in its y-axis.

The frequency characteristic of the system illustrated in FIG. 2 is shown by curves 305, 307, 309 and 311. By using a test for each frequency region, it is possible to completely identify the parameters of the system.

In particular, frequencies at low regions, such as from 0.1 Hz to 10 Hz, for example, result in a differentiation between response signals output from the power filter 307, 309 and response signals output from the motor 305, 311, as indicated by arrows 313 and 315.

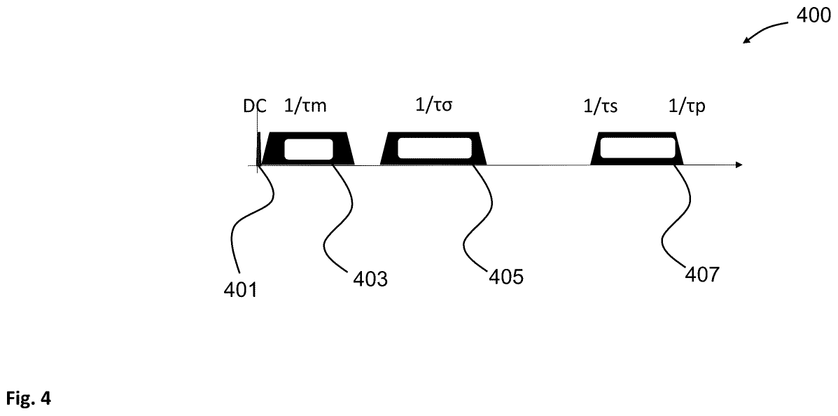

In FIG. 4, a graph 400 is shown that shows a frequency in [Hz] on its x-axis and a DC voltage on its y-axis.

At very low frequencies, a DC test 401 is carried out for measuring stator resistance Rs and filter resistance Rf.

At small frequencies, such as 1/τm, an AC test 403 is carried out for measuring magnetizing inductance Lh and rotor resistance Rr.

At mid-range frequencies, such as 1/τσ a step test 405 is carried out for measuring motor leakage inductance Lσ and filter inductance Lf at four DC biases.

At higher frequencies, such as from 1/τs to 1/τp a frequency sweep test 407 is carried out for determining the ratio of filter inductance Lf and motor leakage inductance Lσ.

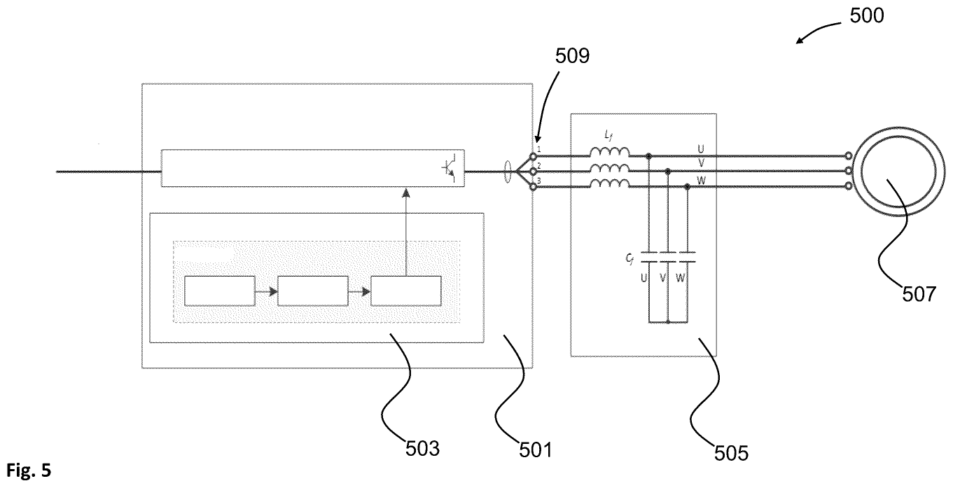

In FIG. 5, a system 500 is shown. The system 500 includes a power converter 501 in form of an Adjustable Speed Drive, a controller 503, a power filter 505 (LC or LCL), and a motor 507.

Here, the power converter 501 includes installation cables 509, which may be insulated on non-insulated and very in their length according to the specific arrangement of the system 500.

The invention is not limited to one of the aforementioned embodiments. It can be modified in many ways.

All features and advantages resulting from the claims, the description and the drawing, including constructive details, spatial arrangements and procedural steps, may be essential for the invention both in themselves and in various combinations.

While the present disclosure has been illustrated and described with respect to a particular embodiment thereof, it should be appreciated by those of ordinary skill in the art that various modifications to this disclosure may be made without departing from the spirit and scope of the present disclosure.

1. A method for estimating electrical parameters of an electric motor and a power filter connected to a power converter,
the method comprising:
injecting an AC signal of different frequencies for a given time window in the power filter and the motor,
measuring a response signal of the power filter and the motor to the injected AC signal,
determining a resonance frequency of the power filter based on the measured response signal,
calculating a ratio of leakage inductances of the power filter and the motor.

2. The method according to claim 1,
wherein
the method continues with estimation of electrical parameters only for the motor, in case no resonance frequency of the power filter is determined.

3. The method according to claim 1,
wherein
the method is carried out while the power filter is connected to the motor.

4. The method according to claim 1,
wherein
a sum of leakage inductances of the power filter and the motor is measured by using a small-signal step voltage test, performed at a given DC offset level.

5. The method according to claim 4,
wherein
inductor and capacitor (LC) resonance present in the signal measured by using the small-signal step voltage test is eliminated by use of a numerical filter, which isolates time constant intervals.

6. The method according to claim 4,
wherein
a ratio of motor and filter leakage inductances is measured by using the injected AC signal at certain level of DC offset level.

7. The method according to claim 1,
wherein
the injection of the AC signal of different frequencies covers a frequency range within a minimum frequency up to a maximum frequency, and is monotonical increased or decreased, or random, or a given order, and covers an entire range with a given step-size.

8. The method according to claim 1,
wherein
further electrical parameters are calculated based on the ratio of leakage inductances of the power filter and the motor, wherein the further electrical parameters are selected from the following list: stator resistance (Rs), rotor resistance (Rr), motor leakage inductance (Lσ), magnetizing inductance (Lh), capacitance (Cf), and filter inductance (Lf), wherein the capacitance (Cf) is also estimated for each phase individually to consider unbalanced cases of capacitance.

9. The method according to claim 8,
wherein
the further electrical parameters are used to adjust control parameters for controlling the motor and/or the power filter.

10. The method according to claim 9,
wherein
the adjustment of the control parameters is carried out periodically and/or in response to a user command.

11. The method according to claim 10,
wherein
a degradation level of the power filter component parameters, capacitances, inductances and resistances (LC or LCL) are periodically compared at different time moments against different given thresholds.

12. The method according to claim 1,
wherein
a DC test is used for measuring stator resistance (Rs) and filter resistance (Rf) parameters, a step test is used for measuring motor leakage inductance (Lσ) und filter induction (Lf) parameters at four DC biases, AC tests are used for measuring magnetizing inductance (Lh) and rotor resistance (Rr) parameters,
wherein the step test is performed with a current target of predefined percentage of a nominal magnetization current,
wherein from the step test and the AC tests, the nominal magnetizing current is identified,
wherein the AC signal of different frequencies is injected only once at a de bias equal to the identified nominal magnetizing current, and
wherein the step test is rerun at the nominal magnetizing current with a current target of predefined percentage of nominal motor current, such that the result of the rerun step test is the sum of motor leakage and filter inductances.

13. The method according to claim 1,
wherein
an ESR of at least the filter capacitor is determined based on the magnitude of the peak resonant frequency of the filter capacitor.

14. A controller for controlling an electric motor,
wherein the controller comprises a processor or FPGA configured to perform the method according to claim 1.

15. A computer program product comprising instructions which, when the program is executed by a computer, cause the computer to carry out the method according to claim 1.
